(19) United States
(12) Patent Application Publication
(10) Pub. No.: US 2025/0393257 A1
(43) Pub. Date: Dec. 25, 2025

(54) MEMORY DEVICE INCLUDING ISOLATION TRANSISTOR

(71) Applicant: SK hynix Inc., Icheon-si (KR)

(72) Inventors: Seong Ho CHOI, Icheon-si (KR); Do Young KIM, Icheon-si (KR); Chang Man SON, Icheon-si (KR); Sun Beom LEE, Icheon-si (KR); Na Ra KIM, Icheon-si (KR); Dong Kyu YOUN, Icheon-si (KR); Go Hyun LEE, Icheon-si (KR); Seung Ho JUNG, Icheon-si (KR)

(21) Appl. No.: 18/919,171

(22) Filed: Oct. 17, 2024

(30) Foreign Application Priority Data
Jun. 19, 2024 (KR) 10-2024-0079323

(51) Int. Cl. H01L 29/78; H10B 41/30; H10B 41/40

(52) U.S. Cl. CPC H10D 30/711; H10B 41/30; H10B 41/40

(57) ABSTRACT

A memory device may include an active region provided on a substrate, a first cell unit and a second cell unit disposed in the active region, and an isolation transistor disposed in the active region between the first cell unit and the second cell unit, with the isolation transistor maintained in a turned-off state.

### CROSS-REFERENCE TO RELATED APPLICATION

The present application claims priority under 35 § U.S.C. 119(a) to Korean patent application number 10-2024-0079323 filed in the Korean Intellectual Property Office on Jun. 19, 2024, which is incorporated herein by reference in its entirety.

### TECHNICAL FIELD

The embodiments of the present disclosure relate to a memory device including an isolation transistor.

### BACKGROUND

Unlike typical random access memory (RAM) devices, a non-volatile memory device may maintain stored data even when power is removed. A read-only memory (ROM) device, which is an example of a nonvolatile memory device capable of maintaining data, may be used in various electronic devices. A ROM device may have characteristics of non-volatile memories, so that stored information is not deleted even when power is removed.

A ROM device may be classified depending on whether data can be input by the user or not. Depending on the use, a programmable ROM device may be sold in an initial state where data is not programmed at the time of manufacturing, so that the user can directly program necessary information on site. A mask ROM device may be sold with data pre-programmed according to the user's order at the time of manufacturing. Depending on the input method, a one-time programmable ROM (OTPROM) or a multi-time programmable ROM (MTPROM) and a PROM device may be used. There are attempts to implement a PROM device as a device that stores data as electric charges, such as an electrically programmable ROM (EPROM) or an electrically erasable PROM (EEPROM).

### SUMMARY

Embodiments of the disclosure may provide a memory device capable of preventing deterioration of device characteristics due to process defects.

Embodiments of the disclosure may provide a memory device including an active region provided on a substrate, a first cell unit and a second cell unit disposed in the active region, and an isolation transistor maintained in a turned-off state and disposed in the active region between the first cell unit and the second cell unit.

Embodiments of the disclosure may provide a memory device including a first cell unit including a first transistor and a second transistor adjacent to the first transistor, a second cell unit including a third transistor and a fourth transistor adjacent to the third transistor, and an isolation transistor disposed between the first cell unit and the second cell unit, connected to the first cell unit and the second cell unit, and maintained in a turned-off state.

Embodiments of the disclosure may provide a memory device including a memory cell structure including a memory cell array, and a peripheral structure disposed below the memory cell structure and including a peripheral circuit for transmitting voltages and signals required for an operation of the memory cell array and a ROM device for storing code data, wherein the ROM device includes an active region provided on a substrate, a first cell unit and a second cell unit disposed in the active region, and an isolation transistor disposed in the active region between the first cell unit and the second cell unit and maintained in a turned-off state.

According to embodiments of the present disclosure, it is possible to prevent the deterioration of device characteristics of a memory device due to process defects

### BRIEF DESCRIPTION OF THE DRAWINGS

FIG. 1 is a block diagram of a ROM device included in a memory device according to embodiments of the present disclosure.

FIG. 2 illustrates a schematic of a portion of FIG. 1 that includes cell units.

FIG. 3 illustrates a planar structure of a portion of FIG. 1 that includes cell units.

FIG. 4 illustrates a cross-section taken along line I-I′ of FIG. 3.

FIG. 5 illustrates an example of a memory device according to an embodiment of the present disclosure.

FIG. 6 illustrates a planar structure of a comparative memory device.

FIG. 7 illustrates a cross-section taken along a line II-II′ of FIG. 6.

FIG. 8 is a block diagram of a memory system including a memory device according to embodiments of the present disclosure.

### DETAILED DESCRIPTION

Hereinafter, various embodiments of the present disclosure will be described in detail with reference to accompanying drawings.

In the accompanying drawings, the two directions parallel to an upper surface of a substrate may be defined as a first direction (FD) and a second direction (SD), respectively, and a direction protruding perpendicularly from the upper surface of the substrate may be defined as a third direction (VD). The first direction (FD) and the second direction (SD) may be substantially perpendicular to each other. The third direction (VD) may be perpendicular to the first direction (FD) and the second direction (SD). In the following specification, ‘vertical’ or ‘vertical direction’ will be used with substantially the same meaning as the third direction (VD). In the drawings, the direction indicated by an arrow and its opposite direction may represent the same direction.

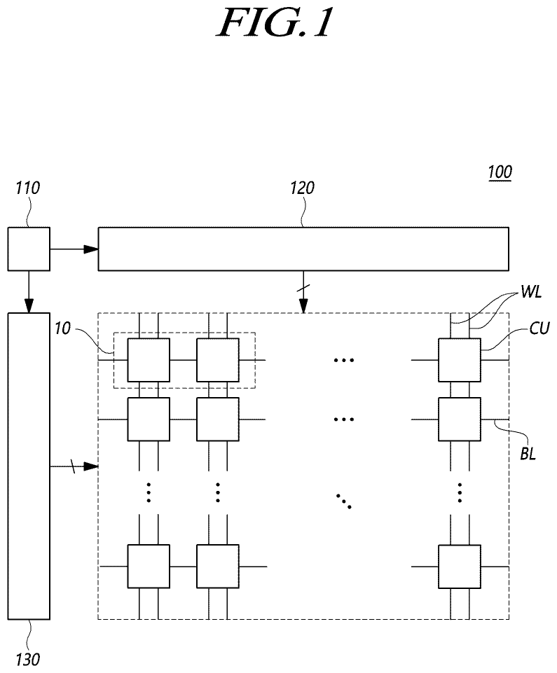

FIG. 1 is a block diagram of a ROM device included in a memory device according to embodiments of the present disclosure.

Referring to FIG. 1, a ROM device 100 may include a control logic 110, a word line selection circuit 120, a bit line selection circuit 130, and a plurality of cell units CU.

The control logic 110 may supply a row address to the word line selection circuit 120 and supply a column address to the bit line selection circuit 130. The word line selection circuit 120 may select one or more of the plurality of word lines WL according to the row address transmitted from the control logic 110. The bit line selection circuit 130 may select one or more of the plurality of bit lines BL according to the column address transmitted from the control logic 110. One cell unit CU may be selected by the selected word line WL and bit line BL.

Each of the plurality of cell units CU may be disposed in an area including at or near an intersection of a pair of word lines WL and one bit line BL. Here, a cell unit CU may mean a pair of cells, that is, two cells. Each cell may include one transistor, and a logic value programmed during manufacturing of the ROM device 100 may be stored in each cell. One cell may store 1 bit of information (0 or 1) or may store two or more bits of multi-bits information. When one cell stores 1 bit of information, a cell unit CU may store two bits of information.

Although not shown, the ROM device 100 may further include a read circuit for reading the logic value stored in each cell unit CU. The read circuit may read the logic value of the selected cell unit CU according to the current flowing in a bit line BL associated with the selected cell unit CU.

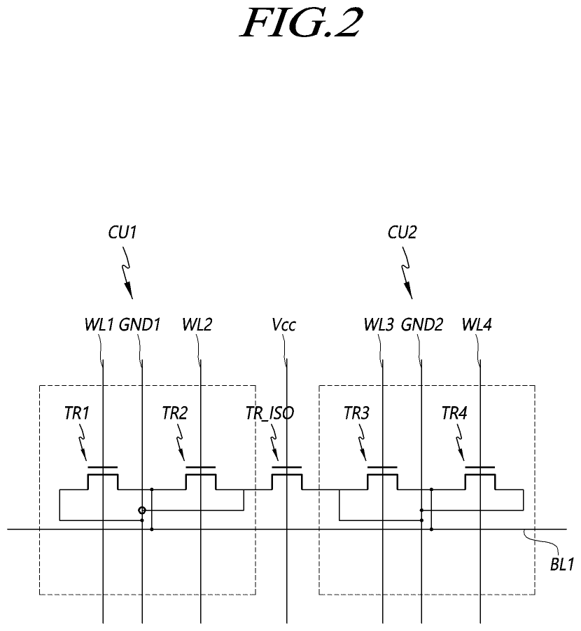

FIG. 2 illustrates a schematic of a portion of FIG. 1 that includes cell units.

FIG. 2 illustrates a portion 10 of FIG. 1 in which the cell units CU include a first cell unit CU1 and a second cell unit CU2. The first cell unit CU1 may be disposed in an area where a first word line WL1 and a second word line WL2 intersect a first bit line BL1. The second cell unit CU2 may be disposed in an area where a third word line WL3 and a fourth word line WL4 intersect a first bit line BL1.

The ROM device 100 may include a first ground line GND1 and a second ground line GND2, which are disposed in parallel with the word lines WL.

The first ground line GND1 may be disposed to overlap with an area where the first cell unit CU1 is disposed. In an embodiment, one first ground line GND1 may be disposed between the first word line WL1 and the second word line WL2.

The second ground line GND2 may be arranged to overlap with an area where the second cell unit CU2 is disposed. In an embodiment, one second ground line GND2 may be disposed between the third word line WL3 and the fourth word line WL4.

The number and arrangement structure of the first ground line GND1 and the second ground line GND2 are not limited to the illustration in FIG. 2. That is, the first ground line GND1 may be disposed in an area that does not overlap with the first cell unit CU1, and the second ground line GND2 may be disposed in an area that does not overlap with the second cell unit CU2. In addition, a pair of first ground lines GND1 and a pair of second ground lines GND2 may be disposed to correspond to the first cell unit CU1 and the second cell unit CU2, respectively. Each of the first ground line GND1 and the second ground line GND2 provides a fixed ground voltage.

The first cell unit CU1 may include a first transistor TR1 and a second transistor TR2. In an embodiment, the first transistor TR1 and the second transistor TR2 may be NMOS transistors. The first transistor TR1 may include the first word line WL1, and the second transistor TR2 may include the second word line WL2.

The second cell unit CU2 may include a third transistor TR3 and a fourth transistor TR4. In an embodiment, the third transistor TR3 and the fourth transistor TR4 may be NMOS transistors. The third transistor TR3 may include the third word line WL3, and the fourth transistor TR4 may include the fourth word line WL4.

The first bit line BL1 may be connected to the first transistor TR1, the second transistor TR2, the third transistor TR3, and the fourth transistor TR4. The first transistor TR1 and the second transistor TR2 may share one drain (as described later), and may be connected to the first bit line BL1 through the shared drain. The third transistor TR3 and the fourth transistor TR4 may share one drain (as described later), and may be connected to the first bit line BL1 through the shared drain. That is, the first cell unit CU1 and the second cell unit CU2 may be both connected to the first bit line BL1.

The source of the first transistor TR1 and the source of the second transistor TR2 may be connected to the first ground line GND1, or may be floated without being connected to the first ground line GND1. Similarly, the source of the third transistor TR3 and the source of the fourth transistor TR4 may be connected to the second ground line GND2, or may be floated without being connected to the second ground line GND2.

A logic value stored in the first cell unit CU1 may vary depending on whether the sources of the first transistor TR1 and the second transistor TR2 are connected to the first ground line GND1. Similarly, a logic value stored in the second cell unit CU2 may vary depending on whether the sources of the third transistor TR3 and the fourth transistor TR4 are connected to the second ground line GND2. For convenience of explanation, in the following descriptions, it will be assumed that one cell stores one bit of information, and that one cell unit CU stores two bits of information.

In an embodiment, the source of the first transistor TR1 may be connected to the first ground line GND1, and the source of the second transistor TR2 may not be connected to the first ground line GND1. When the source of the first transistor TR1 is connected to the first ground line GND1, a read operation performed on the first transistor TR1 may read a logic value “1”. In addition, if the source of the second transistor TR2 is not connected to the first ground line GND1, and the source of the second transistor TR2 is in a floating state, then a logic value “0” may be read when a read operation is performed on the second transistor TR2. That is, in this case, information of “10” may be stored in the first cell unit CU1.

Similarly, in an embodiment, the source of the third transistor TR3 may be connected to the second ground line GND2, and the source of the fourth transistor TR4 may be connected to the second ground line GND2. If the source of the third transistor TR3 is connected to the second ground line GND2, then a logic value “1” may be read when a read operation is performed on the third transistor TR3. In addition, if the source of the fourth transistor TR4 is connected to the second ground line GND2, then a logic value “1” may be read when a read operation is performed on the fourth transistor TR4. That is, in this case, information of “11” may be stored in the second cell unit CU2.

In FIG. 2, the first cell unit CU1 may store information of “10” and the second cell unit CU2 may store information of “11”, but embodiments are not necessarily limited thereto, and each of the first cell unit CU1 and the second cell unit CU2 may store information of “00”, “10”, “01”, or “11”.

For example, the source of the first transistor TR1 and the source of the second transistor TR2 may not be connected to the first ground line GND1. If the source of the first transistor TR1 is not connected to the first ground line GND1, then the source of the first transistor TR1 may be in a floating state, so that a logic value “0” may be read when a read operation is performed on the first transistor TR1. In addition, if the source of the second transistor TR2 is not connected to the first ground line GND1, then the source of the second transistor TR2 may be in a floating state, so that a logic value of “0” may be read when a read operation is performed on the second transistor TR2. That is, in this case, information of “00” may be stored in the first cell unit CU1.

Alternatively, the source of the first transistor TR1 may be not connected to the first ground line GND1, and the source of the second transistor TR2 may be connected to the first ground line GND1. If the source of the first transistor TR1 is not connected to the first ground line GND1, and the source of the first transistor TR1 is in a floating state, then that a logic value of “0” may be read when a read operation is performed on the first transistor TR1. In addition, if the source of the second transistor TR2 is connected to the first ground line GND1, then a logic value “1” may be read when a read operation is performed on the second transistor TR2. That is, in this case, information of “01” may be stored in the first cell unit CU1.

Referring to FIG. 2, the ROM device 100 may further include a gate line Vcc and an isolation transistor TR_ISO. The isolation transistor TR_ISO may include a gate line Vcc.

The gate line Vcc may be arranged parallel to a word line WL. In an embodiment, the gate line Vcc may be located between the first cell unit CU1 and the second cell unit CU2. For example, the gate line Vcc may be positioned between the second word line WL2 and the third word line WL3 as illustrated in FIG. 2. In addition, although not illustrated, the gate line Vcc may also be positioned between the second cell unit CU2 and another cell unit adjacent to the second cell unit CU2, in a different direction opposite from the first cell unit CU1 from a perspective with the second cell unit CU2 as the center.

The isolation transistor TR_ISO may be located between the second transistor TR2 of the first cell unit CU1 and the third transistor TR3 of the second cell unit CU2. In an embodiment, a source of the isolation transistor TR_ISO may be connected to the second transistor TR2, and the source of the isolation transistor TR_ISO and the source of the second transistor TR2 may be shared. A drain of the isolation transistor TR_ISO may be connected to the third transistor TR3, and the drain of the isolation transistor TR_ISO and the source of the third transistor TR3 may be shared.

Alternatively, the drain of the isolation transistor TR_ISO and the source of the second transistor TR2 may be shared, and the source of the isolation transistor TR_ISO and the source of the third transistor TR3 may be shared.

The isolation transistor TR_ISO may be maintained in a turned-off state regardless of the operations of the second transistor TR2 and the third transistor TR3. That is, a voltage for turning off the isolation transistor TR_ISO may be provided to the gate line Vcc. In an embodiment, the isolation transistor TR_ISO may be an NMOS transistor. If the isolation transistor TR_ISO is an NMOS transistor, then a ground voltage may be provided to the gate line Vcc.

Since the isolation transistor TR_ISO remains in a turned-off state regardless of the operation of the second transistor TR2 and the third transistor TR3, no current flows through a channel of the isolation transistor TR_ISO. Therefore, the second transistor TR2 and the third transistor TR3 may be not electrically connected to each other.

Since the isolation transistor TR_ISO is maintained in the turned-off state, if the source of the second transistor TR2 is not connected to the first ground line GND1, then the source of the second transistor TR2 may be in a floating state. Similarly, if the source of the third transistor TR3 is not connected to the second ground line GND2, then the source of the third transistor TR3 may be in a floating state.

In addition, since the isolation transistor TR_ISO is maintained in a turned-off state, even if the source of the second transistor TR2 is connected to the first ground line GND1, the source of the second transistor TR2 may be in a grounded state. Similarly, even if the source of the third transistor TR3 is connected to the second ground line GND2, the source of the third transistor TR3 may be grounded.

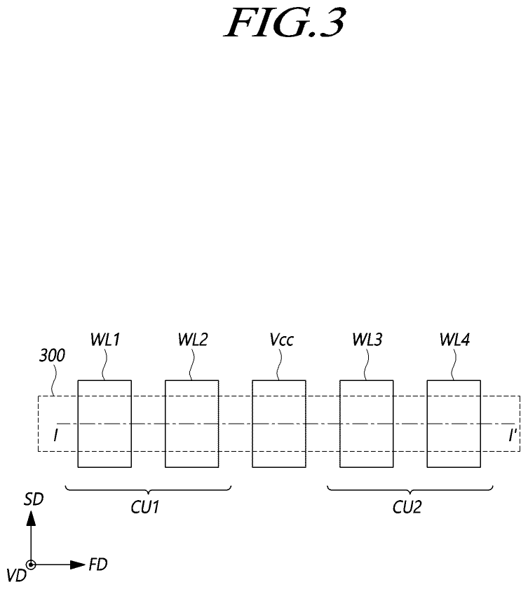

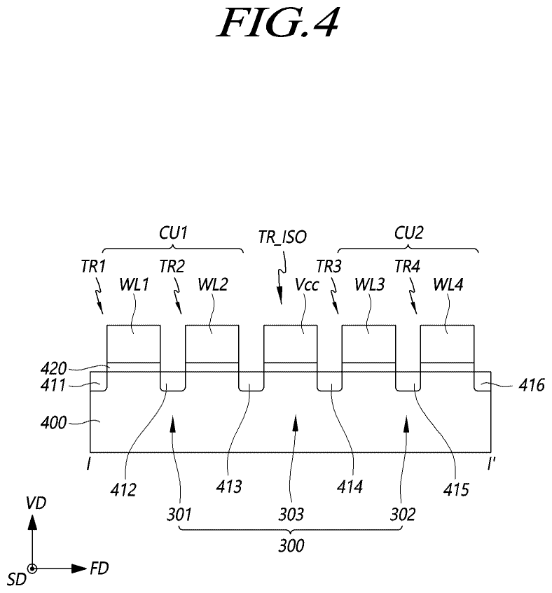

FIG. 3 illustrates a planar structure of a portion of FIG. 1 that includes cell units. FIG. 4 illustrates a cross-section taken along line I-I′ of FIG. 3.

Referring to FIGS. 3 and 4, a ROM device 100 may include a substrate 400, an active region 300, a first cell unit CU1, a second cell unit CU2, and an isolation transistor TR_ISO.

The substrate 400 may include a semiconductor substrate such as a silicon wafer or a silicon-on-insulator (SOI) wafer. The substrate 400 may include a group III-V semiconductor substrate, for example, a compound semiconductor substrate such as GaAs. The substrate 400 may include single crystal silicon, polysilicon, amorphous silicon, single crystal silicon germanium, polycrystalline silicon germanium, carbon-doped silicon, or a combination thereof. In an embodiment, the substrate 400 may be silicon doped with a group III element.

The active region 300 may be provided in the substrate 400. The first cell unit CU1, the second cell unit CU2 and the isolation transistor TR_ISO may be disposed in the active region 300 of a substrate 400. The active region 300 may include a first portion 301 in which the first cell unit CU1 is disposed, a second portion 302 in which the second cell unit CU2 is disposed, and a third portion 303 in which the isolation transistor TR_ISO is disposed. In an embodiment, an upper surface of the third portion 303 of the active region 300 may form the same plane as an upper surface of the first portion 301 of the active region 300 and an upper surface of the second portion 302 of the active region 300.

A plurality of source and drain regions 411, 412, 413, 414, 415 and 416 may be disposed in the active region 300. In an embodiment, the plurality of source and drain regions 411, 412, 413, 414, 415 and 416 may include single crystal silicon having N-type impurities. The N-type impurities may include P, As, or a combination thereof.

Channel regions of a first transistor TR1, a second transistor TR2, an isolation transistor TR_ISO, a third transistor TR3, and a fourth transistor TR4 may be formed between the plurality of source and drain regions 411, 412, 413, 414, 415 and 416, respectively. For example, a channel region of the first transistor TR1 may be formed between the first source region 411 and the first drain region 412.

A gate insulating layer 420 may be disposed in a region that overlaps vertically (VD) with channel regions of the first transistor TR1, the second transistor TR2, the isolation transistor TR_ISO, the third transistor TR3, and the fourth transistor TR4 in the active region 300 of a substrate 400. The gate insulating layer 420 may include silicon oxide, silicon nitride, silicon oxynitride, a high-K dielectric, or a combination thereof.

The first word line WL1, the second word line WL2, the gate line Vcc, the third word line WL3, and the fourth word line WL4 may be disposed on the gate insulating layer 420. In an embodiment, the gate line Vcc may be disposed in the same layer as the first word line WL1, the second word line WL2, the third word line WL3, and the fourth word line WL4. Each of the plurality of word lines WL1, WL2, WL3 and WL4 may include a conductive material such as a metal, a metal oxide, a metal nitride, a metal silicide, polysilicon, conductive carbon, or a combination thereof. In an embodiment, the gate line Vcc may include the same material as a material forming the plurality of word lines WL1, WL2, WL3 and WL4.

As seen in FIG. 3, the first word line WL1, the second word line WL2, the gate line Vcc, the third word line WL3 and the fourth word line WL4 may extend across the active region 300 in the second direction (SD). Each of the first word line WL1, the second word line WL2, the gate line Vcc, the third word line WL3 and the fourth word line WL4 may vertically overlap in the vertical direction (VD) with not only the first cell unit CU1 and the second cell unit CU2, but also with other cell units disposed in a region extending in the second direction (SD).

The transistors included in the first cell unit CU1 may share a drain with each other through a first drain region 412. That is, the first drain region 412 may correspond to the drain region of the first transistor TR1 and the second transistor TR2.

The transistors included in the second cell unit CU2 share a drain with each other through a second drain region 415. That is, the second drain region 415 may correspond to the drain region of the third transistor TR3 and the fourth transistor TR4.

The isolation transistor TR_ISO may share a source or a drain with the second transistor TR2 through a second source region 413, and may share a source or a drain with the third transistor TR3 through a third source region 414. That is, the second source region 413 may correspond to the source region of the second transistor TR2, and may also correspond to the source or drain region of the isolation transistor TR_ISO. Similarly, the third source region 414 may correspond to the source region of the third transistor TR3 and may also correspond to the source or drain region of the isolation transistor TR_ISO.

Although not shown, a first ground line GND1 and a second ground line GND2 may be further disposed on the first word line WL1, the second word line WL2, the gate line Vcc, the third word line WL3 and the fourth word line WL4.

Similar to the first word line WL1, the second word line WL2, the gate line Vcc, the third word line WL3 and the fourth word line WL4, the first ground line GND1 and the second ground line GND2 may extend in the second direction (SD) across the active region 300. Each of the first ground line GND1 and the second ground line GND2 may overlap in the vertical direction (VD) with not only the first cell unit CU1 and the second cell unit CU2, but also with other cell units arranged in a region extending in the second direction (SD).

The first ground line GND1 and the second ground line GND2 may be electrically connected to the first transistor TR1, the second transistor TR2, the third transistor TR3, or the fourth transistor TR4 through the first source region 411, the second source region 413, the third source region 414, or a fourth source region 416.

Although not illustrated, the ROM device 100 may further include a conductive contact for connecting the first ground line GND1 and the second ground line GND2 to at least one of the plurality of source regions 411, 413, 414 and 416.

The conductive contact may be disposed at various positions within the cell unit depending on the logic value stored in the cell unit.

For example, if the first cell unit CU1 stores information of “10”, the source of the first transistor TR1 is required to be connected to the first ground line GND1 and the source of the second transistor TR2 is required to not be connected to the first ground line GND1, so the conductive contact may be connected to the first source region 411, and may connect between the first source region 411 and the first ground line GND1. In addition, the conductive contact may not be disposed between the second source region 413 and the first ground line GND1.

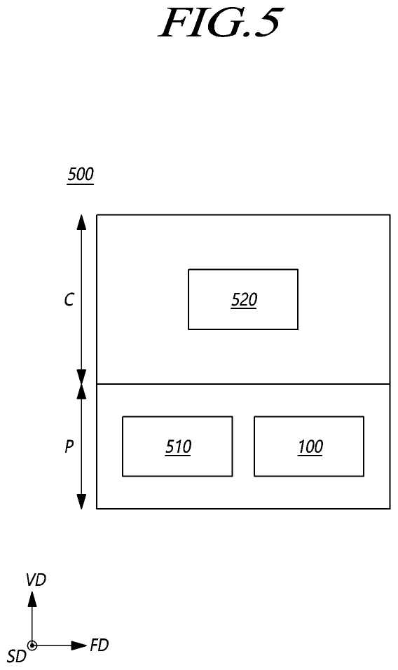

FIG. 5 illustrates an example of a memory device according to an embodiment of the present disclosure.

Referring to FIG. 5, a memory 500 may include a peri-structure or a peripheral structure (P) and a memory cell structure (C).

The memory cell structure (C) may include a memory cell array 520 in which a plurality of memory cells are arranged. Within the memory cell array 520, the memory cells may be arranged in a first direction (FD) or a second direction (SD), i.e., in a two-dimensional manner. Alternatively, in another embodiment, the memory cells may be arranged in a vertical direction (VD), i.e., in a three-dimensional manner.

In an embodiment, the peripheral structure (P) may include a peripheral circuit 510 and a ROM device 100. Alternatively, in another embodiment, the ROM device 100 may exist outside the memory 500. The peripheral circuit 510 may transmit various signals and voltages for the operation of the memory cells to the memory cell array 520. The ROM device 100 may store code data used by program codes required for the operation of the controller. Code data may mean single or multi-bit information stored in the aforementioned cell units.

If the memory cells are disposed in the vertical direction (VD), the memory cell structure (C) and the peripheral structure (P) may be built up vertically on a single wafer. The memory cell structure (C) may include a substrate, various semiconductor devices formed on the substrate, and lines connected to the semiconductor devices. The peripheral structure (P) may include a plurality of pass transistors, a block selection circuit, a page buffer circuit, a plurality of voltage switching circuits, and circuits corresponding to the peripheral circuit 510. After forming various circuits on the peripheral structure (P), a memory cell array 520 may be formed on the peripheral structure (P), and lines for electrically connecting the memory cell array 520 and the circuits formed on the peripheral structure (P) may be formed. In this case, the memory 500 may be defined as having a peri-under-cell (PUC) structure.

Alternatively, the peripheral structure (P) and the memory cell structure (C) may be manufactured on different wafers, and then bonded to each other through a wafer bonding process to become a single unit. In this case, the memory 500 may be defined as having a peri-over-cell (POC) structure.

If the peripheral structure (P) includes a ROM device 100, the ROM device 100 may be disposed within the peripheral structure (P). The cell units of the ROM device 100 may be disposed on a substrate on which various circuits included in the peripheral structure (P) are arranged. That is, the substrate 400 described above with reference to FIG. 4 may correspond to a substrate on which various circuits included in the peripheral structure (P) are disposed.

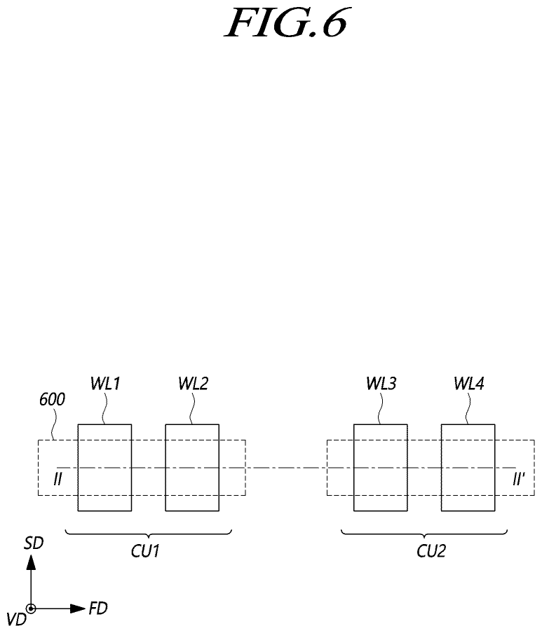

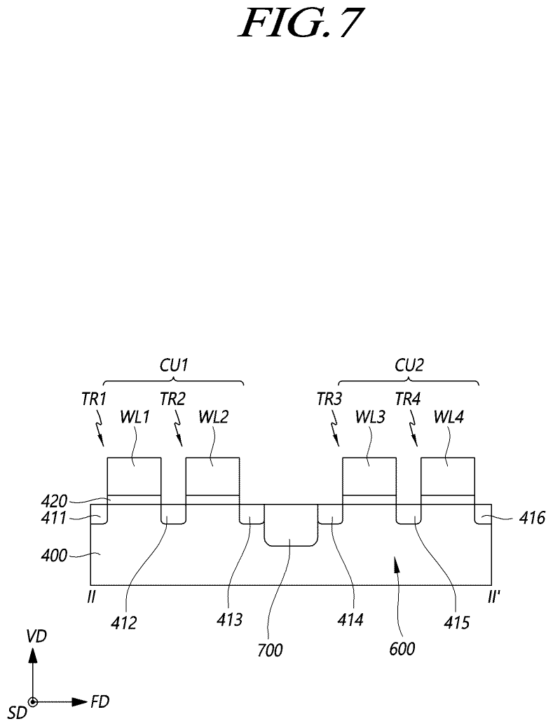

FIG. 6 illustrates a planar structure of a comparative memory device. FIG. 7 illustrates a cross-section taken along a line II-II′ of FIG. 6.

Referring to FIGS. 6 and 7, a device isolation layer 700 may be disposed between cell units on a substrate 400. That is, a device isolation layer 700 may be disposed between a first cell unit CU1 and a second cell unit CU2. The device isolation layer 700 may be formed using a trench device isolation technology such as shallow trench isolation (STI). The device isolation layer 700 may include silicon oxide, silicon nitride, silicon oxynitride, low-K dielectrics, high-K dielectrics, or a combination thereof. Since the device isolation layer 700 is disposed between the first cell unit CU1 and the second cell unit CU2, the active region 600 may be electrically disconnected between the first cell unit CU1 and the second cell unit CU2.

The device isolation layer 700 can serve to insulate the first cell unit CU1 and the second cell unit CU2. That is, the device isolation layer 700 may insulate between transistors included in different cells so that the operation of the transistors included in the second cell unit CU2 is not affected when the transistors included in the first cell unit CU1 are operated. Although not shown, the device isolation layer 700 may also be disposed between a cell unit adjacent to the second cell unit CU2 in a different direction from the first cell unit CU1 and the second cell unit CU2.

However, if an ROM device 100 includes the device isolation layer 700 as above, the active region 600 may become physically separated. Since the device isolation layer 700 is arranged between the cell units, the number of device isolation layers 700 may need to increase to secure more cell units as the ROM device 100 becomes more highly integrated. As the number of device isolation layers 700 increases, the size of the active regions 600 that exist on the substrate 400 may decrease, so the active region 600 may become vulnerable to stress caused by stress generated during the process of manufacturing the ROM device 100. Cracks or dislocations due to stress may be induced around the active region 600 and the device isolation layer 700, and this may cause a defect or deterioration of the characteristics of the ROM device.

Referring to FIG. 3 and FIG. 4 again, in embodiments of the disclosure, the ROM device 100 may include an isolation transistor TR_ISO disposed between the first cell unit CU1 and the second cell unit CU2. A source or a drain of the isolation transistor TR_ISO may be connected to a source of the second transistor TR2 included in the first cell unit CU1 and to a source of the third transistor TR3 included in the second cell unit CU2. In addition, the isolation transistor TR_ISO may include at least a portion of the gate line Vcc, and a ground voltage may be applied to the gate line Vcc.

In addition, in embodiments of the disclosure, the active region 300 may extend from a region overlapping with the first cell unit CU1 to a region overlapping with the second cell unit CU2, and the isolation transistor TR_ISO may be disposed in the active region 300 between the first cell unit CU1 and the second cell unit CU2.

According to embodiments of the present disclosure, a ROM device 100 may include the isolation transistor TR_ISO disposed between a first cell unit CU1 and a second cell unit CU2, and the isolation transistor TR_ISO may include a gate line Vcc to which a ground voltage is applied. Therefore, even when a device isolation layer is not disposed between the first cell unit CU1 and the second cell unit CU2, that is, even when the active region 300 is not separated or not disconnected, it is possible to provide a memory device in which the first cell unit CU1 and the second cell unit CU2 can be insulated from each other.

That is, in embodiments of the disclosure, the active region 300 may extend from the region overlapping with the first cell unit CU1 to the region overlapping with the second cell unit CU2, and a turned-off isolation transistor TR_ISO may be disposed in the active region 300 between the first cell unit CU1 and the second cell unit CU2, so that there may be provided a memory device in which the active region 300 is physically connected while electrically insulating the first cell unit CU1 and the second cell unit CU2 from each other.

Accordingly, memory devices according to the embodiments of the present disclosure can prevent the occurrence of cracks or dislocations that may occur during the manufacturing process, thereby preventing defects or deterioration of the characteristics of the memory device.

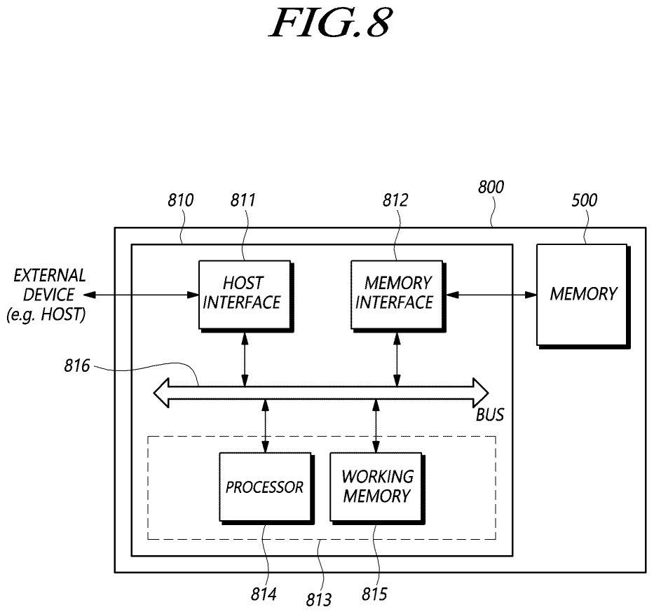

FIG. 8 is a block diagram of a memory system including a memory device according to embodiments of the present disclosure.

Referring to FIG. 8, a memory system 800 may include a memory 500 for storing data, and a controller 810 for controlling the memory 500.

The memory 500 may operate in response to the control of the controller 810. Here, the operation of the memory 500 may include, for example, a read operation, a program operation (also called a “write operation”), and an erase operation.

The memory 500 may be implemented in various types, such as NAND Flash Memory, 3D NAND Flash Memory, NOR Flash Memory, etc.

The memory 500 may receive a command and an address from the controller 810, and may access an area selected by the address from among memory cell arrays 520. That is, the memory 500 may perform an operation indicated by the command for an area selected by the address.

For example, the memory 500 may perform a program operation, a read operation, an erase operation, etc. In this regard, when performing the program operation, the memory 500 can program or write data in an area selected by the address. When performing the read operation, the memory 500 may read data from an area selected by the address. When performing the erase operation, the memory 500 may erase or delete data stored in an area selected by the address.

The controller 810 may control write (i.e., program), read, erase, and background operations for the memory 500. Here, background operations may include, for example, one or more of a garbage collection (GC) operation, a wear leveling (WL) operation, a read reclaim (RR) operation, or a bad block management (BBM) operation.

The controller 810 may control the operation of the memory 500 according to a request from a device (e.g., a host) located outside the memory system 800. Alternatively, the controller 810 may also control the operation of the memory 500 regardless of a request from the host HOST.

The host HOST may be a computer, an ultra-mobile PC (UMPC), a workstation, a personal digital assistant (PDA), a tablet, a mobile phone, a smartphone, an e-book, or a portable multimedia player (PMP), a portable game console, a navigation device, a black box, a digital camera, a digital multimedia broadcasting (DBM) players, a smart television, a digital voice recorder, a digital voice player, a digital image recorder, a digital image player, a digital video recorder, a digital video player, a storage of a data center, one of the various electronic devices constituting a home network, one of the various electronic devices constituting a telematics network, an radio frequency identification (RFID) device, a mobile device (e.g., vehicle, robot, drone) driven under human control or capable of autonomous driving, etc.

The host HOST may include at least one operating system. The operating system may generally manage and control the functions and operations of the host and control mutual operations between the host and the memory system 800. The operating system may be divided into a general operating system and a mobile operating system depending on the mobility of the host HOST.

Meanwhile, the host HOST and the controller 810 may be separate devices. In some cases, the controller 810 may be integrated with the host HOST and implemented as a single device. Hereinafter, for convenience of explanation, examples assume that the controller 810 and the host HOST are separate devices.

Referring to FIG. 8, the controller 810 may include a memory interface 812 and a control circuit 813, and may further include a host interface 811.

The host interface 811 may provide an interface for communication with the host HOST. For example, the host interface 811 may provide an interface utilizing at least one of various interface protocols, such as an universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, or a private protocol.

The control circuit 813 may receive a command through the host interface 811 and perform an operation of processing the received command in response to the reception of the command from the host HOST.

The memory interface 812 may be connected to the memory 500, and may provide an interface for communication with the memory 500. That is, the memory interface 812 may be configured to provide an interface between the memory 500 and the controller 810 in response to the control of the control circuit 813.

The control circuit 813 may perform the overall control operation of the controller 810 to control the operation of the memory 500. For this purpose, as an example, the control circuit 813 may include one or more of a processor 814 and a working memory 815, and may also optionally include an error detection and correction circuit, etc.

The processor 814 may control all operations of the controller 810 and perform logical operations. The processor 814 may communicate with the host HOST through the host interface 811 and communicate with the memory 500 through the memory interface 812.

The processor 814 may perform a function of a flash translation layer (FTL). The processor 814 may convert a logical block address (LBA) provided by the host into a physical block address (PBA) through the flash translation layer (FTL). The flash translation layer (FTL) may receive a logical block address (LBA) using a mapping table and convert the logical block address (LBA) into a physical block address (PBA).

There may be several address mapping methods used by the flash translation layer depending on a mapping unit. The address mapping methods may include a page mapping method, a block mapping method, and a hybrid mapping method.

The processor 814 may randomize data received from the host. For example, the processor 814 may randomize data received from the host using a preset randomizing seed. The randomized data may be provided to the memory 500, and may be programmed into the memory cell array of the memory 500.

The processor 814 may derandomize data received from the memory 500 during a read operation. For example, the processor 814 may derandomize data received from the memory 500 using a derandomizing seed. The derandomized data may be output to the host.

The processor 814 may control the operation of the controller 810 by executing firmware. That is, the processor 814 may execute or drive firmware loaded into the working memory 815 at boot time in order to control the overall operation of the controller 810 and perform logical operations.

The firmware may be a program that is executed within the memory system 800 to drive the memory system 800, and may include various functional layers. For example, the firmware may include binary data in which codes for executing each of the functional layers are defined.

For example, the firmware may include one or more of a flash translation layer (FTL) that performs a conversion function between a logical address requested from the host to the memory system 800 and a physical address of the memory 500, a host interface layer (HIL) that interprets a command requested to the memory system 800 as a storage device from the host and transmits the interpreted command to the flash translation layer (FTL), and a flash interface layer (FIL) that transmits a command instructed by the flash translation layer (FTL) to the memory 500.

The firmware may be loaded into the working memory 815 from, for example, the memory 500 or a separate non-volatile memory (e.g., ROM, NOR Flash) located outside the memory 500. When executing a boot operation after power-on, the processor 814 may first load all or part of the firmware into the working memory 815. The processor 814 may perform a logical operation

defined in the firmware loaded into the working memory 815 to control the overall operation of the controller 810. The processor 814 may store the result of performing the logical operation defined in the firmware into the working memory 815. The processor 814 may control the controller 810 to generate a command or signal according to the result of performing the logical operation defined in the firmware. If the part of the firmware defining the logical operation to be performed is not loaded into the working memory 815, then the processor 814 may generate an event (e.g., an interrupt) to load the corresponding part of the firmware into the working memory 815.

The processor 814 may load metadata required to run the firmware from the memory 500. The metadata may be data for managing the memory 500, and may include management information on user data stored in the memory 500.

The firmware may be updated while the memory system 800 is being manufactured or while the memory system 800 is being executed. The controller 810 may download new firmware from outside the memory system 800 and update the existing firmware with the new firmware.

The working memory 815 may store firmware, program code, commands or data required to drive the controller 810. The working memory 815 may include, for example, one or more of static RAM (SRAM), dynamic RAM (DRAM) and synchronous DRAM (SDRAM) as volatile memory.

A bus 816 may be configured to provide a channel between the components 811, 812, 814 and 815 of the controller 810. The bus 816 may include, for example, a control bus for transmitting various control signals, commands, and a data bus for transmitting various data.

Some of the components 811, 812, 814 and 815 of the controller 810 described above may be omitted, or some of the components 811, 812, 814 and 815 of the controller 810 may be integrated into a single device. In some cases, one or more other components may be added in addition to the components described above of the controller 810.

The above description is merely an illustrative description of the technical idea of the present disclosure, and those skilled in the art to which the present disclosure pertains may create various modifications and variations without departing from the essential characteristics of the present disclosure. In addition, the embodiments disclosed in the present disclosure are not intended to limit the technical idea of the present disclosure but to explain it, and therefore the scope of the technical idea of the present disclosure is not limited by these embodiments. The protection scope of the present disclosure should be interpreted by the following claims, and all technical ideas within a scope equivalent thereto should be interpreted as being included in the scope of rights of the present disclosure.

What is claimed is:

1. A memory device comprising:
an active region provided on a substrate;
a first cell unit and a second cell unit disposed in the active region; and
an isolation transistor maintained in a turned-off state and disposed in the active region between the first cell unit and the second cell unit.

2. The memory device of claim 1, wherein the first cell unit and the second cell unit are adjacent and arranged in a first direction,
wherein the isolation transistor includes a gate line, and the gate line is disposed to cross the active region in a second direction perpendicular to the first direction.

3. The memory device of claim 2, wherein each of the first cell unit and the second cell unit includes a pair of word lines arranged parallel to each other on the active region,
wherein the gate line of the isolation transistor is disposed in the same layer as the word lines of the first cell unit and the second cell unit.

4. The memory device of claim 1, wherein the isolation transistor is an NMOS transistor and receives a ground voltage regardless of an operation of the first cell unit and the second cell unit.

5. The memory device of claim 1, wherein the active region includes:
a first portion in which the first cell unit is disposed;
a second portion in which the second cell unit is disposed; and
a third portion in which the isolation transistor is disposed,
wherein an upper surface of the third portion is disposed on substantially the same plane as upper surfaces of the first portion and the second portion.

6. The memory device of claim 1, wherein each of the first cell unit and the second cell unit stores two bits of information.

7. The memory device of claim 1, wherein the first cell unit and the second cell unit are connected to a single bit line.

8. The memory device of claim 1, wherein the isolation transistor shares a source with one of the transistors included in the first cell unit or the second cell unit, and shares a drain with the other of the transistors included in the first cell unit or the second cell unit.

9. The memory device of claim 1, wherein the first cell unit and the second cell unit are electrically separated from each other.

10. A memory device comprising:
a first cell unit including a first transistor and a second transistor adjacent to the first transistor;
a second cell unit including a third transistor and a fourth transistor adjacent to the third transistor; and
an isolation transistor disposed between the first cell unit and the second cell unit, connected to the first cell unit and the second cell unit, and maintained in a turned-off state.

11. The memory device of claim 10, wherein the isolation transistor includes a gate line,
wherein each of the first transistor, the second transistor, the third transistor, and the fourth transistor includes one word line,
wherein the gate line is disposed on the same layer as the word line.

12. The memory device of claim 10, wherein the isolation transistor is disposed between the second transistor and the third transistor, and shares a source or a drain with the second transistor and the third transistor, respectively.

13. The memory device of claim 10, wherein the first transistor and the second transistor share a drain, and the third transistor and the fourth transistor share a drain.

14. The memory device of claim 13, wherein the first cell unit is connected to a single bit line through the drain shared by the first transistor and the second transistor, and the second cell unit is connected to a single bit line through the drain shared by the third transistor and the fourth transistor.

15. The memory device of claim 10, wherein the second transistor and the third transistor are electrically separated from each other.

16. The memory device of claim 10, wherein each of the first cell unit and the second cell unit stores two bits of information.

17. A memory device comprising:
a memory cell structure including a memory cell array; and
a peripheral structure disposed below the memory cell structure and including a peripheral circuit for transmitting voltages and signals required for an operation of the memory cell array and a ROM device for storing code data,
wherein the ROM device comprises:
an active region provided on a substrate;
a first cell unit and a second cell unit disposed in the active region; and
an isolation transistor disposed in the active region between the first cell unit and the second cell unit and maintained in a turned-off state.

18. The memory device of claim 17, wherein each of the first cell unit and the second cell unit stores two bits of information.

19. The memory device of claim 17, wherein the isolation transistor includes a gate line,
wherein each of the first cell unit and the second cell unit includes a pair of word lines arranged parallel to each other on the active region,
wherein the gate line is disposed on the same layer as the word lines.

20. The memory device of claim 17, wherein the active region includes:
a first portion in which the first cell unit is disposed;
a second portion in which the second cell unit is disposed; and
a third portion in which the isolation transistor is disposed,
wherein an upper surface of the third portion, an upper surface of the first portion and an upper surface of the second portion are disposed on substantially the same plane.
